(19) United States
(12) Patent Application Publication
(10) Pub. No.: US 2022/0200233 A1
(43) Pub. Date: Jun. 23, 2022

(54) Light Emitting Device And Projector

(71) Applicant: Seiko Epson Corporation, Tokyo (JP)

(72) Inventors: Takafumi NODA, Matsumoto (JP); Yoji KITANO, Chino (JP)

(21) Appl. No.: 17/644,807

(22) Filed: Dec. 17, 2021

(30) Foreign Application Priority Data
Dec. 18, 2020 (JP) 2020-210209

(51) Int. Cl. H01S 5/026; G03B 21/20; H01S 5/34

(52) U.S. Cl. CPC H01S 5/0261; H01S 5/34; G03B 21/2033

(57) ABSTRACT

A light emitting device includes a substrate, a transistor, a light emitting element, and an interconnection configured to electrically couple the transistor and the light emitting element to each other, wherein the transistor includes a first impurity region provided to the substrate, a second impurity region which is provided to the substrate, and is same in conductivity type as the first impurity region, and a gate, the light emitting element has a stacked body having a plurality of columnar parts, each of the columnar parts includes a first semiconductor layer, a second semiconductor layer, and a light emitting layer, the first semiconductor layer is disposed between the substrate and the light emitting layer, the interconnection is a third impurity region provided to the substrate, the stacked body is provided to the third impurity region, the third impurity region is same in conductivity type as the first semiconductor layer, the third impurity region is electrically coupled to the first semiconductor layer, and the third impurity region is continuous with the first impurity region.

The present application is based on, and claims priority from JP Application Serial Number 2020-210209, filed Dec. 18, 2020, the disclosure of which is hereby incorporated by reference herein in its entirety.

### BACKGROUND

### 1. Technical Field

The present disclosure relates to a light emitting device and a projector.

### 2. Related Art

Semiconductor lasers are promising as high-luminance next-generation light sources. In particular, a semiconductor laser to which nano-columns are applied is expected to be able to realize narrow-radiation angle high-power light emission due to an effect of a photonic crystal derived from the nano-columns.

For example, in JP-A-2009-105182 (Document 1), there is described an optical integration element in which a light emitting element having a plurality of columnar parts, and a transistor for driving the light emitting element are integrated into the same substrate.

However, in Document 1, since the light emitting element and the transistor are electrically coupled to each other with metal wiring, the device grows in size in some cases.

### SUMMARY

A light emitting device according to an aspect of the present disclosure includes a substrate, a transistor provided to the substrate, a light emitting element provided to the substrate, and an interconnection configured to electrically couple the transistor and the light emitting element to each other, wherein the transistor includes a first impurity region provided to the substrate, a second impurity region which is provided to the substrate, and is same in conductivity type as the first impurity region, and a gate configured to control an electrical current between the first impurity region and the second impurity region, the light emitting element has a stacked body having a plurality of columnar parts, each of the columnar parts includes a first semiconductor layer, a second semiconductor layer different in conductivity type from the first semiconductor layer, and a light emitting layer disposed between the first semiconductor layer and the second semiconductor layer, the first semiconductor layer is disposed between the substrate and the light emitting layer, the interconnection is a third impurity region provided to the substrate, the stacked body is provided to the third impurity region, the third impurity region is same in conductivity type as the first semiconductor layer, the third impurity region is electrically coupled to the first semiconductor layer, and the third impurity region is continuous with the first impurity region.

A projector according to another aspect of the present disclosure includes the light emitting device according to the above aspect.

### BRIEF DESCRIPTION OF THE DRAWINGS

FIG. 1 is a cross-sectional view schematically showing a light emitting device according to an embodiment.

FIG. 2 is a cross-sectional view schematically showing a manufacturing process of the light emitting device according to the embodiment.

FIG. 3 is a cross-sectional view schematically showing the manufacturing process of the light emitting device according to the embodiment.

FIG. 4 is a cross-sectional view schematically showing the manufacturing process of the light emitting device according to the embodiment.

FIG. 5 is a cross-sectional view schematically showing the manufacturing process of the light emitting device according to the embodiment.

FIG. 6 is a cross-sectional view schematically showing the manufacturing process of the light emitting device according to the embodiment.

FIG. 7 is a cross-sectional view schematically showing the manufacturing process of the light emitting device according to the embodiment.

FIG. 8 is a cross-sectional view schematically showing the manufacturing process of the light emitting device according to the embodiment.

FIG. 9 is a cross-sectional view schematically showing a light emitting device according to a first modified example of the embodiment.

FIG. 10 is a cross-sectional view schematically showing a light emitting device according to a second modified example of the embodiment.

FIG. 11 is a diagram schematically showing a projector according to the embodiment.

### DESCRIPTION OF AN EXEMPLARY EMBODIMENT

A preferred embodiment of the present disclosure will hereinafter be described in detail using the drawings. It should be noted that the embodiment described hereinafter does not unreasonably limit the contents of the present disclosure as set forth in the appended claims. Further, all of the constituents described hereinafter are not necessarily essential elements of the present disclosure.

### 1. Light Emitting Device

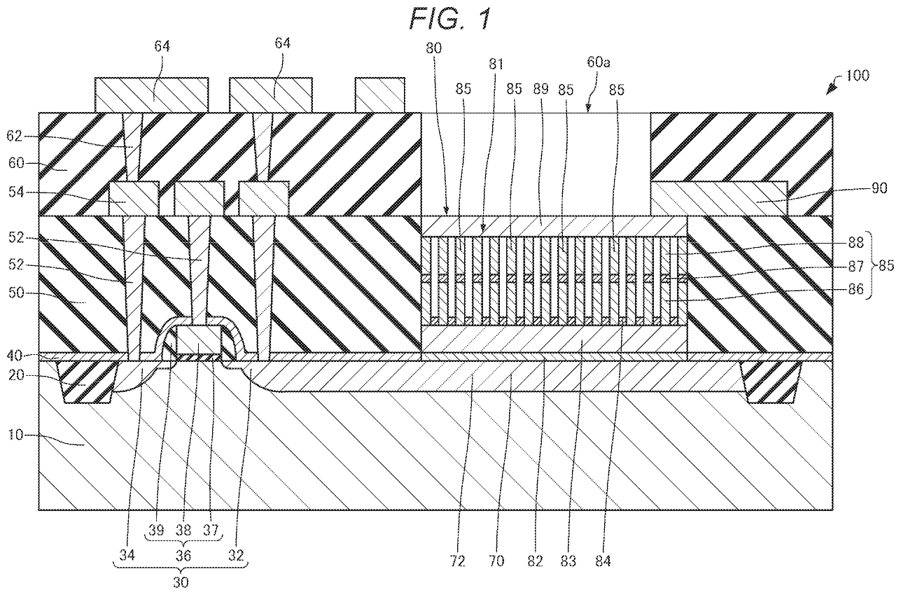

First, a light emitting device according to the present embodiment will be described with reference to the drawings. FIG. 1 is a cross-sectional view schematically showing the light emitting device 100 according to the present embodiment.

As shown in FIG. 1, the light emitting device 100 has, for example, a substrate 10, an element separation area 20, a transistor 30, a passivation film 40, a first interlayer insulating film 50, first via-interconnections 52, first metal interconnections 54, a second interlayer insulating film 60, second via-interconnections 62, second metal interconnections 64, an interconnection 70, a light emitting element 80, and an extraction interconnection 90. The light emitting device 100 has a monolithic structure having the transistor 30 and the light emitting element 80 provided to the same substrate 10.

The substrate 10 is a semiconductor substrate. The substrate 10 is, for example, a silicon substrate. The substrate 10 can be, for example, a p-type silicon substrate.

The element separation area 20 is provided to the substrate 10. The element separation area 20 is, for example, LOCOS (Local Oxidation of Silicon) or STI (Shallow Trench Isolation). The element separation area 20 is capable of electrically separating the transistor 30 and the light emitting element 80 from other elements not shown.

The transistor 30 is provided to the substrate 10. The transistor 30 can constitute CMOS (Complementary Metal Oxide Semiconductor), or can be a bipolar transistor. The transistor 30 constitutes a circuit for driving the light emitting element 80. The transistor 30 has a first impurity region 32, a second impurity region 34, and a gate 36.

The first impurity region 32 is provided to the substrate 10. The first impurity region 32 is, for example, an n-type impurity region. The first impurity region 32 functions as one of the source and the drain of the transistor 30.

The second impurity region 34 is provided to the substrate 10. The second impurity region 34 is separated from the first impurity region 32. The conductivity type of the second impurity region 34 is the same as the conductivity type of the first impurity region 32. The second impurity region 34 functions as the other of the source and the drain of the transistor 30.

The gate 36 is disposed on the substrate 10. The gate 36 has a gate insulating film 37, a gate electrode 38, and a sidewall 39. The material of the gate insulating film 37 and the sidewall 39 is, for example, silicon oxide. The material of the gate electrode 38 is, for example, Al, Cu, Al—Cu (an alloy of Al and Cu), W, or Ti. The gate 36 controls an electrical current between the first impurity region 32 and the second impurity region 34.

The passivation film 40 covers the transistor 30. In the illustrated example, the passivation film 40 is disposed on the gate 36 and the impurity regions 32, 34. The passivation film 40 is, for example, a silicon nitride film, a silicon oxynitride film, or a silicon oxide film.

The first interlayer insulating film 50 covers the transistor 30. The first interlayer insulating film 50 is disposed on the substrate 10 via the passivation film 40. The first via-interconnections 52 are respectively disposed in via holes provided to the first interlayer insulating film 50. The first via-interconnections 52 are coupled to the transistor 30. In the illustrated example, there are disposed the three first via-interconnections 52, and the three first via-interconnections 52 are coupled respectively to the first impurity region 32, the second impurity region 34, and the gate 36. The first metal interconnections 54 are disposed on the first interlayer insulating film 50. The first metal interconnections 54 are respectively coupled to the first via-interconnections 52.

The second interlayer insulating film 60 is disposed on the first interlayer insulating film 50. The second interlayer insulating film 60 covers the first metal interconnections 54. The second interlayer insulating film 60 is provided with a through hole 60a. The second via-interconnections 62 are respectively disposed in via holes provided to the second interlayer insulating film 60. The second metal interconnections 64 are disposed on the second interlayer insulating film 60. The second metal interconnections 64 are respectively coupled to the second via-interconnections 62. The material of the interlayer insulating films 50, 60 is, for example, silicon oxide. The material of the via-interconnections 52, 62 and the metal interconnections 54, 64 is, for example, Al, Cu, Al—Cu, W, or Ti.

The interconnection 70 electrically couples the transistor 30 and the light emitting element 80 to each other. The interconnection 70 corresponds to a third impurity region 72 provided to the substrate 10. In other words, the interconnection 70 is a diffusion layer interconnection formed of the third impurity region 72 provided to the substrate 10. The third impurity region 72 is, for example, an n-type impurity region. The third impurity region 72 is continuous with the first impurity region 32. The first impurity region 32 and the third impurity region 72 are integrally disposed. The substrate 10 has the impurity regions 32, 34, and 72.

The light emitting element 80 is provided to the substrate 10. The light emitting element 80 has a stacked body 81 and an electrode 89. The light emitting element 80 is, for example, a semiconductor laser. The stacked body 81 is provided to the third impurity region 72. In the illustrated example, the stacked body 81 is disposed on the third impurity region 72. The stacked body 81 has a strain relaxing layer 82, a buffer layer 83, a mask layer 84, and a plurality of columnar parts 85.

In the present specification, when taking a light emitting layer 87 as a reference in a stacking direction of the stacked body 81 (hereinafter also referred to simply as a “stacking direction”), the description will be presented assuming a direction from the light emitting layer 87 toward a second semiconductor layer 88 as an “upward direction,” and a direction from the light emitting layer 87 toward a first semiconductor layer 86 as a “downward direction.” Further, a direction perpendicular to the stacking direction is also referred to as an “in-plane direction.” Further, the “stacking direction of the stacked body 81” means a stacking direction of the first semiconductor layer 86 and the light emitting layer 87 in the columnar part 85.

The strain relaxing layer 82 is disposed on the third impurity region 72. The strain relaxing layer 82 is disposed between the substrate 10 and the first semiconductor layer 86. The lattice constant of the strain relaxing layer 82 takes a value between the lattice constant of the substrate 10 and the lattice constant of the first semiconductor layer 86 of the columnar part 85. The strain relaxing layer 82 is, for example, an AlN layer. The strain relaxing layer 82 is formed to be thin so as not to be high in resistance with respect to the electrical current from the third impurity region 72. The thickness of the strain relaxing layer 82 is, for example, no smaller than 3 nm and no larger than 500 nm.

The buffer layer 83 is disposed on the strain relaxing layer 82. The buffer layer 83 is, for example, an Si-doped n-type GaN layer.

The mask layer 84 is disposed on the buffer layer 83. The mask layer 84 is a layer for forming the columnar parts 85. The mask layer 84 is, for example, a silicon oxide layer, a titanium layer, a titanium oxide layer, or an aluminum oxide layer.

The columnar parts 85 are disposed on the buffer layer 83. The columnar parts 85 each have a columnar shape protruding upward from the buffer layer 83. In other words, the columnar parts 85 protrude upward from the substrate 10 via the buffer layer 83. The columnar part 85 is also referred to as, for example, a nano-column, a nano-wire, a nano-rod, or a nano-pillar. A planar shape of the columnar part 85 is, for example, a polygon such as a regular hexagon, or a circle.

The diametrical size of the columnar part 85 is, for example, no smaller than 50 nm and no larger than 500 nm. By setting the diametrical size of the columnar part 85 to be no larger than 500 nm, it is possible to obtain the light emitting layer 87 made of crystal high in quality, and at the same time, it is possible to reduce a strain inherent in the light emitting layer 87. Thus, it is possible to amplify light generated in the light emitting layer 87 with high efficiency.

It should be noted that when the planar shape of the columnar part 85 is a circle, the “diametrical size of the columnar part” means the diameter of the circle, and when the planar shape of the columnar part 85 is not a circular shape, the “diametrical size of the columnar part” means the diameter of the minimum encompassing circle. For example, when the planar shape of the columnar part 85 is a polygonal shape, the diametrical size of the columnar part is the diameter of a minimum circle including the polygonal shape inside, and when the planar shape of the columnar part 85 is an ellipse, the diametrical size of the columnar part 85 is the diameter of a minimum circle including the ellipse inside.

There is disposed a plurality of the columnar parts 85. An interval between the columnar parts 85 adjacent to each other is, for example, no smaller than 1 nm and no larger than 500 nm. The plurality of columnar parts 85 is arranged at a predetermined pitch in a predetermined direction when viewed from the stacking direction. The plurality of columnar parts 85 is arranged so as to form, for example, a triangular lattice. It should be noted that the arrangement of the plurality of columnar parts 85 is not particularly limited, and the plurality of columnar parts 85 can be arranged to form a square grid. The plurality of columnar parts 85 can develop an effect of a photonic crystal.

It should be noted that the “pitch of the columnar parts” means a distance between the centers of the columnar parts 85 adjacent to each other along the predetermined direction. When the planar shape of the columnar part 85 is a circle, the “center of the columnar part” means the center of the circle, and when the planar shape of the columnar part 85 is not a circular shape, the “center of the columnar part” means the center of the minimum encompassing circle. For example, when the planar shape of the columnar part 85 is a polygonal shape, the center of the columnar part 85 is the center of a minimum circle including the polygonal shape inside, and when the planar shape of the columnar part 85 is an ellipse, the center of the columnar part 85 is the center of a minimum circle including the ellipse inside.

The columnar parts 85 each have the first semiconductor layer 86, the light emitting layer 87, and the second semiconductor layer 88.

The first semiconductor layer 86 is disposed on the buffer layer 83. The first semiconductor layer 86 is disposed between the substrate 10 and the light emitting layer 87. The first semiconductor layer 86 is, for example, an Si-doped n-type GaN layer. The conductivity type of the third impurity region 72 is the same as the conductivity type of the first semiconductor layer 86. The third impurity region 72 is electrically coupled to the first semiconductor layer 86. The third impurity region 72 functions as one of electrodes for injecting an electrical current into the light emitting layer 87.

The light emitting layer 87 is disposed on the first semiconductor layer 86. The light emitting layer 87 is disposed between the first semiconductor layer 86 and the second semiconductor layer 88. The light emitting layer generates light in response to injection of the electrical current. The light emitting layer 87 has a well layer and a barrier layer which are each an i-type semiconductor layer, and which are not intentionally doped with any impurity. The well layer is, for example, an InGaN layer. The barrier layer is, for example, a GaN layer. The light emitting layer 87 has an MQW (Multiple Quantum Well) structure constituted by the well layers and the barrier layers.

It should be noted that the numbers of the well layers and the barrier layers constituting the light emitting layer 87 are not particularly limited. For example, the number of the well layers disposed can be one, and in that case, the light emitting layer 87 has an SQW (Single Quantum Well) structure.

The second semiconductor layer 88 is disposed on the light emitting layer 87. The second semiconductor layer 88 is a layer different in conductivity type from the first semiconductor layer 86. The second semiconductor layer 88 is, for example, an Mg-doped p-type GaN layer. The first semiconductor layer 86 and the second semiconductor layer 88 are cladding layers having a function of confining the light in the light emitting layer 87.

It should be noted that although not shown in the drawings, an OCL (Optical Confinement Layer) can be disposed between the first semiconductor layer 86 and the light emitting layer 87. Further, an EBL (Electron Blocking Layer) can be disposed between the light emitting layer 87 and the second semiconductor layer 88.

In the light emitting device 100, a pin diode is constituted by the second semiconductor layer 88 of the p-type, the light emitting layer 87 of the i-type doped with no impurity, and the first semiconductor layer 86 of the n-type. In the light emitting device 100, when a forward bias voltage of the pin diode is applied between the third impurity region 72 and the electrode 89, the electrical current is injected into the light emitting layer 87, and recombination of electrons and holes occurs in the light emitting layer 87. The recombination causes light emission. The light generated in the light emitting layer 87 propagates in an in-plane direction to form a standing wave due to the effect of the photonic crystal caused by the plurality of columnar parts 85, and is then gained by the light emitting layer 87 to cause laser oscillation. Then, the light emitting element 80 emits positive first-order diffracted light and negative first-order diffracted light as a laser beam in the stacking direction. The light is emitted through the through hole 60a provided to the second interlayer insulating film 60. Due to the through hole 60a, it is possible to increase the light extraction efficiency. It should be noted that the light proceeding toward the substrate 10 is reflected by the substrate 10, and is then emitted through the through hole 60a.

The electrode 89 is disposed on the second semiconductor layer 88. The electrode 89 is electrically coupled to the second semiconductor layer 88. It is also possible for the second semiconductor layer 88 to have ohmic contact with the electrode 89. The electrode 89 is the other of the electrodes for injecting the electrical current into the light emitting layer 87. As the electrode 89, there is used, for example, ITO (indium tin oxide).

The extraction interconnection 90 disposed on the electrode 89 and the first interlayer insulating film 50. In the illustrated example, the extraction interconnection 90 is covered with the second interlayer insulating film 60. The material of the extraction interconnection 90 is, for example, the same as the material of the first metal interconnections 54. The extraction interconnection 90 is an interconnection for making the electrical current flow through the electrode 89.

It should be noted that although the light emitting layer 87 of the InGaN type is described above, as the light emitting layer 87, there can be used a variety of types of material system capable of emitting light in response to injection of an electrical current in accordance with the wavelength of the light to be emitted. It is possible to use semiconductor materials of, for example, an AlGaN type, an AlGaAs type, an InGaAs type, an InGaAsP type, an InP type, a GaP type, or an AlGaP type.

Further, although not shown in the drawings, a light blocking part for blocking the light from the light emitting element 80 can be disposed between the transistor 30 and the light emitting element 80. Thus, it is possible to reduce the influence of the light from the light emitting element 80 on the operation of the transistor 30. The light blocking part can be the same in material as the via-interconnections 52, and can be formed in a step of forming the via-interconnections 52 at the same time. Alternatively, it is possible for the light blocking part to be formed by growing a semiconductor layer, and then disposing a metal layer on the semiconductor layer.

Further, the light emitting element 80 is not limited to the laser, and can also be an LED (Light Emitting Diode).

The light emitting device 100 exerts, for example, the following functions and advantages.

In the light emitting device 100, the interconnection 70 corresponds to the third impurity region 72 provided to the substrate 10, the stacked body 81 is disposed on the third impurity region 72, the conductivity type of the third impurity region 72 is the same as the conductivity type of the first semiconductor layer 86, the third impurity region 72 is electrically coupled to the first semiconductor layer 86, and the third impurity region is continuous with the first impurity region 32.

Therefore, in the light emitting device 100, it is possible to achieve reduction in size compared to when using a metal interconnection as the interconnection for electrically coupling the transistor and the light emitting element to each other. For example, when using the metal interconnection, the wiring becomes complicated, and the device grows in size in some cases. Further, in the light emitting device 100, since there is no need to dispose an element separation area between the transistor 30 and the light emitting element 80, it is possible to dispose the transistor 30 and the light emitting element 80 close to each other, and thus, it is possible to achieve the reduction in size.

Further, in the light emitting device 100, since the light emitting element 80 has the plurality of columnar parts 85, it is possible to minimize the strain even when the transistor 30 and the light emitting element 80 are disposed on the same substrate. Therefore, it is possible to realize the light emitting element 80 high in efficiency. Further, since a hybrid mounting technology such as transfer mounting or substrate bonding is not used, it is possible to achieve reduction in cost.

In the light emitting device 100, the stacked body 81 has the strain relaxing layer 82 disposed between the substrate 10 and the first semiconductor layer 86, and the lattice constant of the strain relaxing layer 82 takes a value between the lattice constant of the substrate 10 and the lattice constant of the first semiconductor layer 86. Therefore, in the light emitting device 100, it is possible to reduce the strain caused in the first semiconductor layer 86 compared to when the strain relaxing layer 82 is not disposed.

In the light emitting device 100, there is included the passivation film 40 for covering the transistor 30. Therefore, in the light emitting device 100, it is possible to reduce the damage to be applied to the transistor 30 due to the heat when forming the light emitting element 80 compared to when the passivation film 40 is not disposed. When forming the light emitting element 80, the heat around 1000° C. is applied in some cases.

### 2. Method of Manufacturing Light Emitting Device

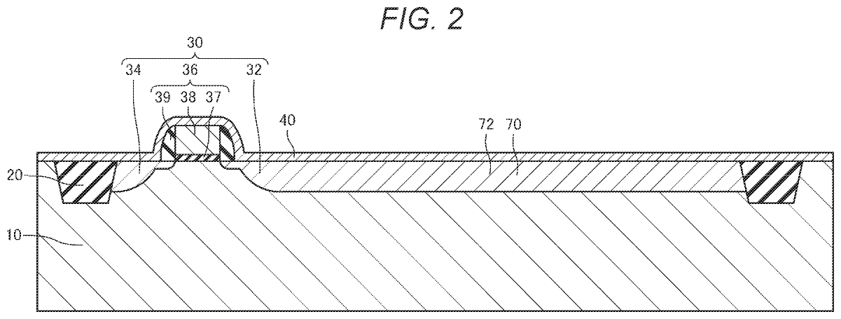

Then, a method of manufacturing the light emitting device 100 according to the present embodiment will be described with reference to the drawings. FIG. 2 through FIG. 8 are cross-sectional views schematically showing a manufacturing process of the light emitting device 100 according to the present embodiment.

As shown in FIG. 2, the element separation area 20 is provided to the substrate 10. The element separation area 20 is formed using, for example, the LOCOS method or the STI method.

Then, the gate insulating film 37 is formed on the substrate 10. The gate insulating film 37 is formed using, for example, a thermal oxidation method. Subsequently, the gate electrode 38 is formed on the gate insulating film 37. The gate electrode 38 is formed using, for example, a sputtering method, a CVD (Chemical Vapor Deposition) method, or a vacuum deposition method. Then, the sidewall 39 is formed on a side surface of the gate electrode 38. The sidewall 39 is formed by forming a silicon oxide film using, for example, the CVD method, and then etching back the silicon oxide film. Due to the present step, it is possible to form the gate 36.

Then, the first impurity region 32, the second impurity region 34, and the third impurity region 72 are formed using, for example, ion injection. The first impurity region 32 and the third impurity region 72 are formed integrally. Due to the present step, it is possible to form the transistor 30.

Then, the passivation film 40 is formed on the substrate 10 so as to cover the transistor 30. The passivation film 40 is formed using, for example, the sputtering method or the CVD method.

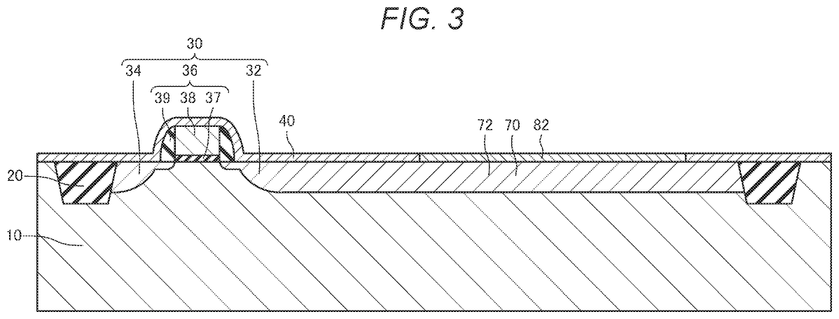

As shown in FIG. 3, the passivation film 40 is partially removed by etching, and then the strain relaxing layer 82 is formed in the portion where the passivation film 40 is removed. The strain relaxing layer 82 is formed using, for example, the CVD method or the sputtering method.

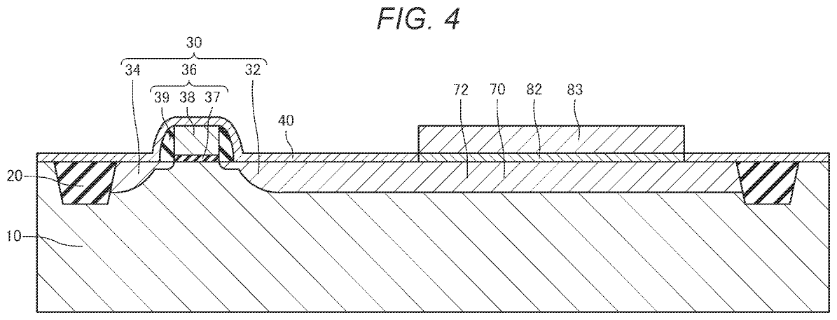

As shown in FIG. 4, the buffer layer 83 is grown epitaxially on the strain relaxing layer 82. As the method of achieving the epitaxial growth, there can be cited, for example, an MOCVD (Metal Organic Chemical Vapor Deposition) method and an MBE (Molecular Beam Epitaxy) method. The buffer layer 83 is selectively grown on the strain relaxing layer 82.

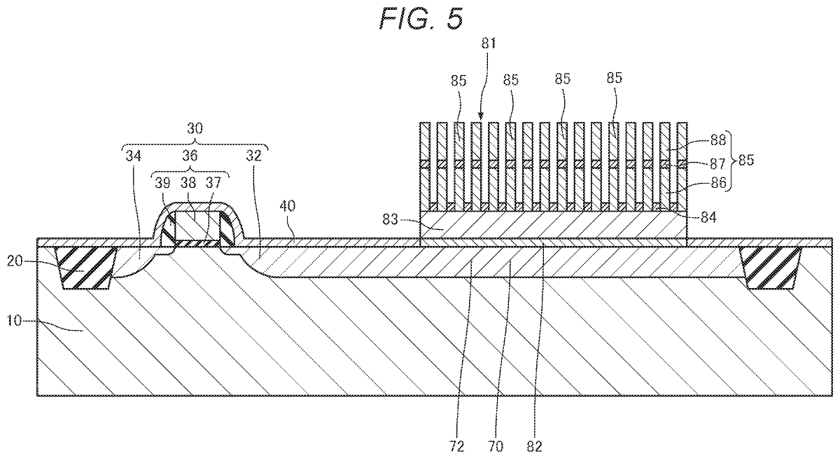

As shown in FIG. 5, the mask layer 84 is formed on the buffer layer 83. The mask layer 84 is formed by deposition using, for example, an electron beam evaporation method or a spattering method, and patterning. The patterning process is performed using a photolithography process and an etching process.

Then, the first semiconductor layer 86, the light emitting layer 87, and the second semiconductor layer 88 are grown epitaxally in this order on the buffer layer 83 using the mask layer 84 as a mask. As the method of achieving the epitaxial growth, there can be cited, for example, the MOCVD method and the MBE method. Due to the present step, it is possible to form the plurality of columnar parts 85. Further, due to the present step, it is possible to form the stacked body 81.

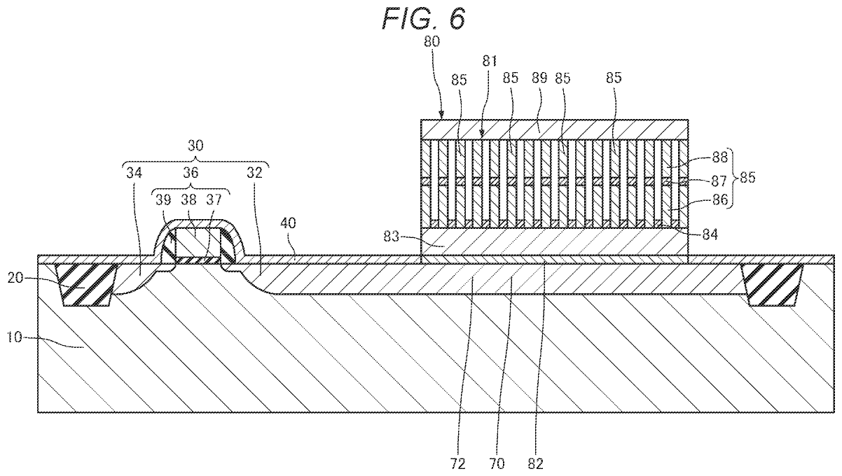

As shown in FIG. 6, the electrode 89 is formed on the second semiconductor layer 88. The electrode 89 is formed using, for example, a vacuum deposition method. Due to the present step, it is possible to form the light emitting element 80. It should be noted that although not shown in the drawings, it is possible to form a passivation film covering the light emitting element 80.

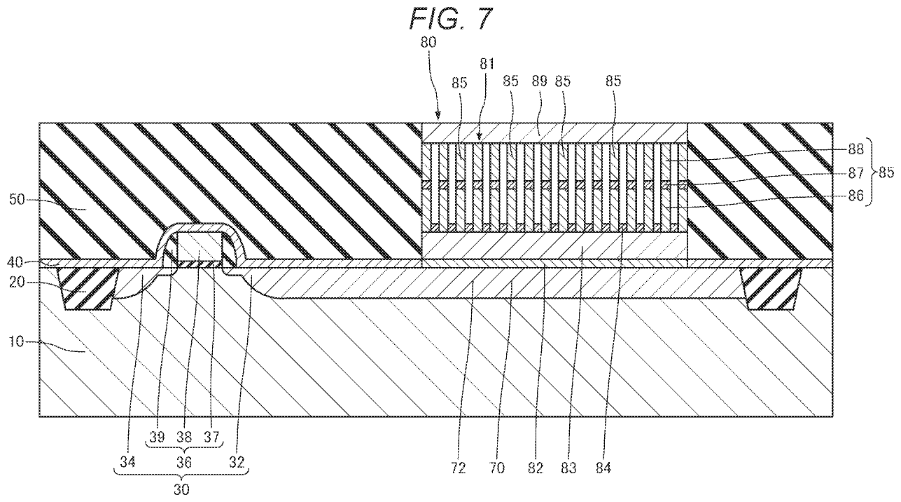

As shown in FIG. 7, the first interlayer insulating film 50 is formed on the passivation film 40 so as to cover the transistor 30. The first interlayer insulating film 50 is formed using, for example, a spin coat method.

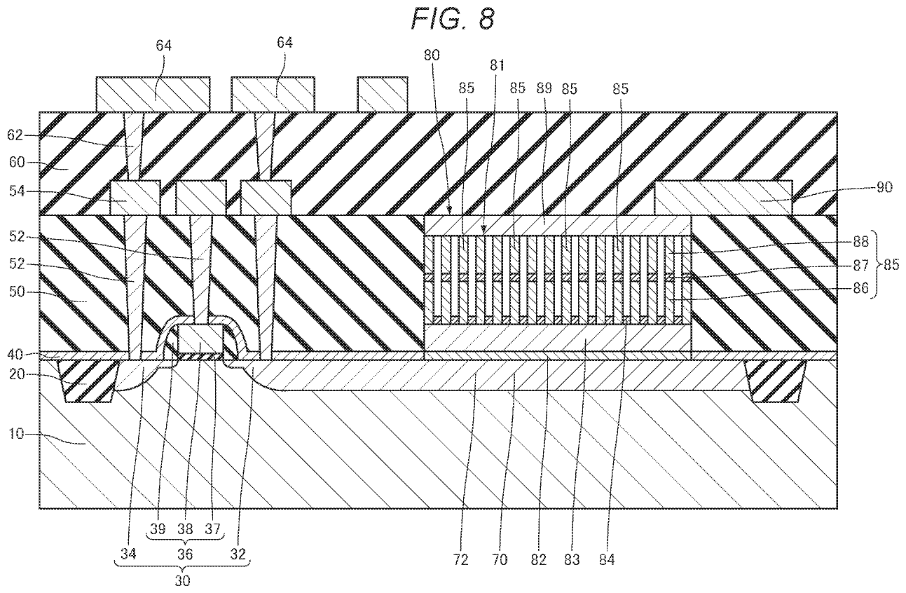

As shown in FIG. 8, the via holes are formed by patterning the first interlayer insulating film 50, and then the first via-interconnections 52 are formed in the respective via holes. Then, the first metal interconnections 54 are formed respectively on the first via-interconnections 52. Further, the extraction interconnection 90 is formed on the electrode 89. The first metal interconnections 54 and the extraction interconnection 90 are formed in the same step. The first via-interconnections 52, the first metal interconnections 54, and the extraction interconnection 90 are formed using, for example, a plating method, the sputtering method, or the CVD method.

Then, the second interlayer insulating film 60 is formed on the first interlayer insulating film 50. The second interlayer insulating film 60 is formed using, for example, the spin coat method.

Then, the via holes are formed by patterning the second interlayer insulating film 60, and then the second via-interconnections 62 are formed in the respective via holes. Then, the second metal interconnections 64 are formed respectively on the second via-interconnections 62. The second via-interconnections 62 and the second metal interconnections 64 are formed using, for example, the plating method, the sputtering method, or the CVD method.

As shown in FIG. 1, the second interlayer insulating film 60 is patterned to form the through hole 60a.

Due to the steps described hereinabove, it is possible to manufacture the light emitting device 100.

### 3. Modified Examples of Light Emitting Device

### 3.1. First Modified Example

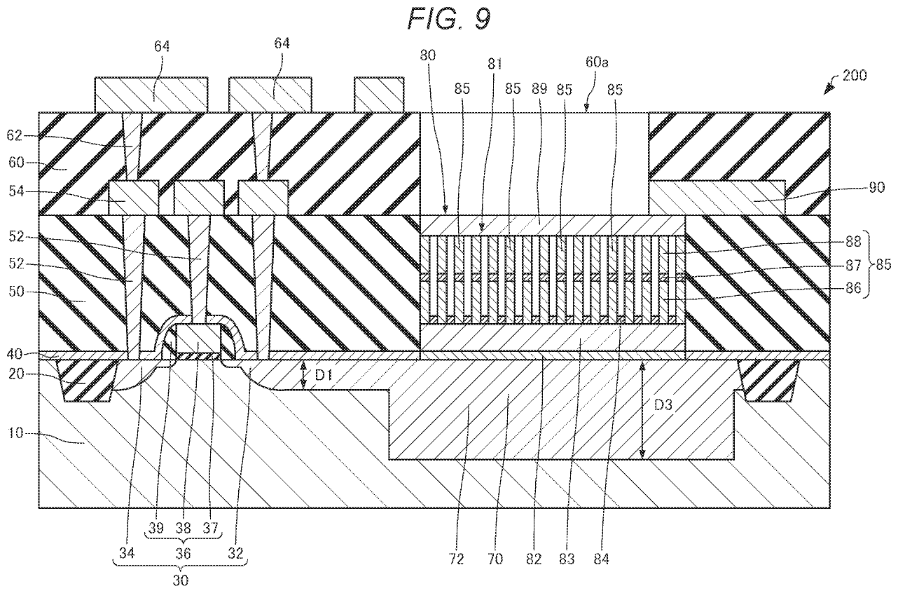

Then, a light emitting device according to a first modified example of the present embodiment will be described with reference to the drawings. FIG. 9 is a cross-sectional view schematically showing the light emitting device 200 according to the first modified example of the present embodiment.

Hereinafter, in the light emitting device 200 according to the first modified example of the present embodiment, members having substantially the same functions as those of the constituent members of the light emitting device 100 according to the present embodiment described above will be denoted by the same reference symbols, and detailed descriptions thereof will be omitted. The same will be applied to a light emitting device according to a second modified example described later of the present embodiment.

As shown in FIG. 1, in the light emitting device 100 described above, the depth of the first impurity region 32 and the depth of the third impurity region 72 are the same as each other.

In contrast, in the light emitting device 200, the depth D3 of the third impurity region 72 is larger than the depth D1 of the first impurity region 32 as shown in FIG. 9. The depth D1 is a maximum size in the stacking direction of the first impurity region 32. The depth D3 is a maximum size in the stacking direction of the third impurity region 72. In the illustrated example, the third impurity region 72 does not have a portion having a depth other than the depth D3. The depth D1 is, for example, no smaller than 50 μm and no larger than 500 μm. The depth D3 is, for example, no smaller than 100 μm and no larger than 2000 μm.

When viewed from the stacking direction, the area of the third impurity region 72 is larger than the area of the stacked body 81. The stacked body 81 is disposed only on the third impurity region 72. The stacked body 81 is not disposed on a region other than the third impurity region 72.

The first impurity region 32 and the third impurity region 72 are formed in steps different from each other. For example, the third impurity region 72 is formed first, and then, the first impurity region 32 is formed. It should be noted that it is possible to form the first impurity region 32 first, and then, form the third impurity region 72.

In the light emitting device 200, the depth D3 of the third impurity region 72 is larger than the depth D1 of the first impurity region 32. Therefore, even when a crystal defect due to the stress in the strain relaxing layer 82 supposedly occurs in the third impurity region 72, it is possible to reduce a difference between the resistance of the first impurity region 32 and the resistance of the third impurity region 72 compared to when, for example, the depth D3 is the same as the depth D1.

In the light emitting device 200, the area of the third impurity region 72 is larger than the area of the stacked body 81 when viewed from the stacking direction. Therefore, in the light emitting device 200, it is possible to dispose the stacked body 81 only on the third impurity region 72.

### 3.2. Second Modified Example

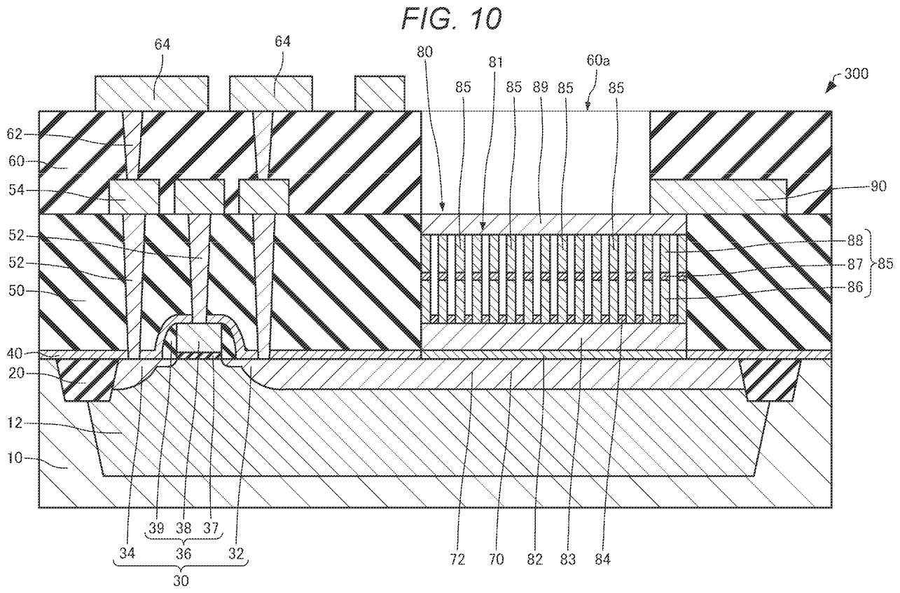

Then, a light emitting device according to the second modified example of the present embodiment will be described with reference to the drawings. FIG. 10 is a cross-sectional view schematically showing the light emitting device 300 according to the second modified example of the present embodiment.

The light emitting device 300 is different from the light emitting device 100 described above in the point that the substrate 10 has a well 12 as shown in FIG. 10.

The depth of the well 12 is larger than the depth of the impurity regions 32, 34, and 72. The well 12 is different in conductivity type from the first impurity region 32. The well 12 is, for example, a p-type well. The transistor 30 is provided to the well 12. The first impurity region 32, the second impurity region 34, and the third impurity region 72 are provided to the wall 12.

The well 12 is formed by, for example, performing ion injection before forming the impurity regions 32, 34, and 72.

In the light emitting device 300, the substrate 10 has the well 12 different in conductivity type from the first impurity region 32, and the first impurity region 32, the second impurity region 34, and the third impurity region 72 are provided to the well 12. Therefore, in the light emitting device 300, it is possible to enhance the insulating property between the substrate 10 and the impurity regions 32, 34, and 72 compared to when the well 12 is not provided.

### 4. Projector

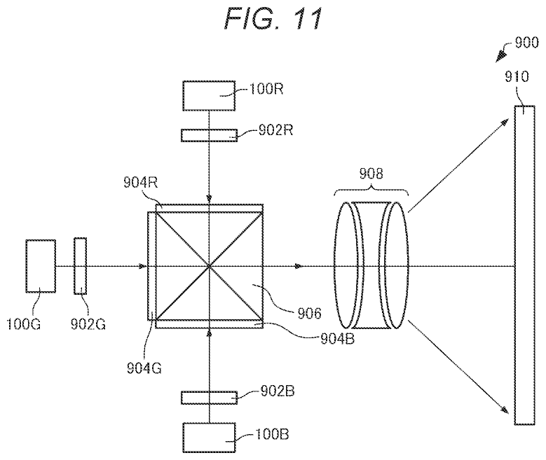

Then, a projector according to the present embodiment will be described with reference to the drawings. FIG. 11 is a diagram schematically showing the projector 900 according to the present embodiment.

The projector 900 has the light emitting devices 100 as, for example, light sources.

The projector 900 includes a housing not shown, a red light source 100R, a green light source 100G, and a blue light source 100B which are disposed inside the housing, and respectively emit red light, green light, and blue light. It should be noted that in FIG. 11, the red light source 100R, the green light source 100G, and the blue light source 100B are simplified for the sake of convenience.

The projector 900 further includes a first optical element 902R, a second optical element 902G, a third optical element 902B, a first light modulation device 904R, a second light modulation device 904G, a third light modulation device 904B, and a projection device 908 all installed inside the housing. The first light modulation device 904R, the second light modulation device 904G, and the third light modulation device 904B are each, for example, a transmissive liquid crystal light valve. The projection device 908 is, for example, a projection lens.

The light emitted from the red light source 100R enters the first optical element 902R. The light emitted from the red light source 100R is collected by the first optical element 902R. It should be noted that the first optical element 902R can be provided with other functions than the light collection. The same applies to the second optical element 902G and the third optical element 902B described later.

The light collected by the first optical element 902R enters the first light modulation device 904R. The first light modulation device 904R modulates the incident light in accordance with image information. Then, the projection device 908 projects an image formed by the first light modulation device 904R on a screen 910 in an enlarged manner.

The light emitted from the green light source 100G enters the second optical element 902G. The light emitted from the green light source 100G is collected by the second optical element 902G.

The light collected by the second optical element 902G enters the second light modulation device 904G. The second light modulation device 904G modulates the incident light in accordance with the image information. Then, the projection device 908 projects an image formed by the second light modulation device 904G on the screen 910 in an enlarged manner.

The light emitted from the blue light source 100B enters the third optical element 902B. The light emitted from the blue light source 100B is collected by the third optical element 902B.

The light collected by the third optical element 902B enters the third light modulation device 904B. The third light modulation device 904B modulates the incident light in accordance with the image information. Then, the projection device 908 projects an image formed by the third light modulation device 904B on the screen 910 in an enlarged manner.

Further, it is possible for the projector 900 to include a cross dichroic prism 906 for combining the light emitted from the first light modulation device 904R, the light emitted from the second light modulation device 904G, and the light emitted from the third light modulation device 904B with each other to guide the light thus combined to the projection device 908.

The three colors of light respectively modulated by the first light modulation device 904R, the second light modulation device 904G, and the third light modulation device 904B enter the cross dichroic prism 906. The cross dichroic prism 906 is formed by bonding four rectangular prisms to each other, and is provided with a dielectric multilayer film for reflecting the red light and a dielectric multilayer film for reflecting the blue light disposed on the inside surfaces. The three colors of light are combined with each other by these dielectric multilayer films, and thus, the light representing a color image is formed. Then, the light thus combined is projected on the screen 910 by the projection device 908, and thus, an enlarged image is displayed.

In the light emitting device 100, since the light emitting element 80 and the transistor 30 for driving the light emitting element 80 are provided to the same substrate, it is possible to perform tone control and ON/OFF control pixel by pixel.

It should be noted that although not shown in the drawings, the red light source 100R, the green light source 100G, and the blue light source 100B can be provided to the same substrate. Thus, it is possible to constitute an imager with RGB pixels, and it is possible to form an imager integrated with a drive circuit.

Further, it is possible for the red light source 100R, the green light source 100G, and the blue light source 100B to directly form the images by controlling the light emitting devices 100 as the pixels of the image in accordance with the image information without using the first light modulation device 904R, the second light modulation device 904G, and the third light modulation device 904B. Then, it is also possible for the projection device 908 to project the images formed by the red light source 100R, the green light source 100G, and the blue light source 100B on the screen 910 in an enlarged manner.

Further, although the transmissive liquid crystal light valves are used as the light modulation devices in the example described above, it is also possible to use light valves other than the liquid crystal light valves, or to use reflective light valves. As such light valves, there can be cited, for example, reflective liquid crystal light valves and Digital Micromirror Device™. Further, the configuration of the projection device is appropriately modified in accordance with the type of the light valves used.

Further, it is also possible to apply the light source to a light source device of a scanning type image display device having a scanning unit as an image forming device for scanning the surface of the screen with the light from the light source to thereby display an image with a desired size on the display surface.

The light emitting devices according to the embodiment described above can also be used for other devices than projectors. As the applications other than projectors, there can be cited a light source of, for example, a pair of smart glasses, indoor and outdoor illumination, a backlight for a display, a laser printer, a scanner, an in-car light, a sensor using light, and communication equipment. When using the light emitting device according to the embodiment described above as a sensor, it is possible to provide areas having wavelength sensitivities different from each other and a retrieving circuit (ROIC) to the same substrate at the same time. Further, the light emitting device according to the embodiment described above can also be applied to a light emitting element of an LED display having microscopic light emitting elements disposed in an array to display an image. Further, the LED display to which the light emitting devices according to the embodiment described above are applied can be used as a display device of the pair of smart glasses.

The embodiment and the modified examples described above are illustrative only, and the present disclosure is not limited to the embodiment and the modified examples. For example, it is also possible to arbitrarily combine the embodiment and the modified examples with each other.

The present disclosure includes configurations substantially the same as the configuration described as the embodiment, for example, configurations having the same function, the same way, and the same result, or configurations having the same object and the same advantage. Further, the present disclosure includes configurations obtained by replacing a non-essential part of the configuration described as the embodiment. Further, the present disclosure includes configurations providing the same functions and advantages, and configurations capable of achieving the same object as those of the configuration described as the embodiment. Further, the present disclosure includes configurations obtained by adding a known technology to the configuration described as the embodiment.

The following contents derive from the embodiment and the modified examples described above.

A light emitting device according to an aspect includes a substrate, a transistor provided to the substrate, a light emitting element provided to the substrate, and an interconnection configured to electrically couple the transistor and the light emitting element to each other, wherein the transistor includes a first impurity region provided to the substrate, a second impurity region which is provided to the substrate, and is same in conductivity type as the first impurity region, and a gate configured to control an electrical current between the first impurity region and the second impurity region, the light emitting element has a stacked body having a plurality of columnar parts, each of the columnar parts includes a first semiconductor layer, a second semiconductor layer different in conductivity type from the first semiconductor layer, and a light emitting layer disposed between the first semiconductor layer and the second semiconductor layer, the first semiconductor layer is disposed between the substrate and the light emitting layer, the interconnection is a third impurity region provided to the substrate, the stacked body is provided to the third impurity region, the third impurity region is same in conductivity type as the first semiconductor layer, the third impurity region is electrically coupled to the first semiconductor layer, and the third impurity region is continuous with the first impurity region.

According to this light emitting device, it is possible to achieve reduction in size compared to when using a metal interconnection as the interconnection for electrically coupling the transistor and the light emitting element to each other.

In the light emitting device according to the aspect, the third impurity region may be larger in depth than the first impurity region.

According to this light emitting device, even when a crystal defect due to a stress in the strain relaxing layer supposedly occurs, it is possible to reduce the difference between the resistance of the first impurity region and the resistance of the third impurity region.

In the light emitting device according to the aspect, when viewed from a stacking direction of the first semiconductor layer and the light emitting layer, the third impurity region may be larger in area than the stacked body.

According to this light emitting device, it is possible to dispose the stacked body only in the third impurity region.

In the light emitting device according to the aspect, the stacked body may have a strain relaxing layer disposed between the substrate and the first semiconductor layer, and a lattice constant of the strain relaxing layer may have a value between a lattice constant of the substrate and a lattice constant of the first semiconductor layer.

According to this light emitting device, it is possible to reduce the strain caused in the first semiconductor layer compared to when the strain relaxing layer is not disposed.

In the light emitting device according to the aspect, there may further be included a passivation film configured to cover the transistor.

According to this light emitting device, it is possible to reduce the damage to be applied to the transistor due to the heat generated when forming the light emitting element compared to when the passivation film is not disposed.

In the light emitting device according to the aspect, the substrate has a well different in conductivity type from the first impurity region, and the first impurity region, the second impurity region, and the third impurity region may be provided to the well.

According to this light emitting device, it is possible to enhance the insulating property between the substrate and the first through third impurity regions compared to when the well is not disposed.

A projector according to another aspect includes the light emitting device according to the above aspect.

What is claimed is:

1. A light emitting device comprising:
a substrate;
a transistor provided to the substrate;
a light emitting element provided to the substrate; and
an interconnection configured to electrically couple the transistor and the light emitting element to each other, wherein
the transistor includes
a first impurity region provided to the substrate,
a second impurity region which is provided to the substrate, and is same in conductivity type as the first impurity region, and
a gate configured to control an electrical current between the first impurity region and the second impurity region,
the light emitting element has a stacked body having a plurality of columnar parts,
each of the columnar parts includes
a first semiconductor layer,
a second semiconductor layer different in conductivity type from the first semiconductor layer, and
a light emitting layer disposed between the first semiconductor layer and the second semiconductor layer,
the first semiconductor layer is disposed between the substrate and the light emitting layer,
the interconnection is a third impurity region provided to the substrate,
the stacked body is provided to the third impurity region,
the third impurity region is same in conductivity type as the first semiconductor layer,
the third impurity region is electrically coupled to the first semiconductor layer, and
the third impurity region is continuous with the first impurity region.

2. The light emitting device according to claim 1, wherein
the third impurity region is larger in depth than the first impurity region.

3. The light emitting device according to claim 2, wherein
when viewed from a stacking direction of the first semiconductor layer and the light emitting layer, the third impurity region is larger in area than the stacked body.

4. The light emitting device according to claim 1, wherein
the stacked body has a strain relaxing layer disposed between the substrate and the first semiconductor layer, and
a lattice constant of the strain relaxing layer has a value between a lattice constant of the substrate and a lattice constant of the first semiconductor layer.

5. The light emitting device according to claim 1, further comprising:
a passivation film configured to cover the transistor.

6. The light emitting device according to claim 1, wherein
the substrate has a well different in conductivity type from the first impurity region, and
the first impurity region, the second impurity region, and the third impurity region are provided to the well.

7. A projector comprising:
the emitting device according to claim 1.
